(19) United States
(12) Patent Application Publication
(10) Pub. No.: US 2025/0081770 A1
(43) Pub. Date: Mar. 6, 2025

(54) DISPLAY DEVICE

(71) Applicant: Samsung Display Co., LTD., Yongin-si (KR)

(72) Inventors: Tae Ho KIM, Yongin-si (KR); Seung Jun LEE, Yongin-si (KR); Yong Su LEE, Yongin-si (KR); Jae Woo LEE, Yongin-si (KR); Sang Min JEON, Yongin-si (KR)

(73) Assignee: Samsung Display Co., LTD., Yongin-si (KR)

(21) Appl. No.: 18/604,496

(22) Filed: Mar. 14, 2024

(30) Foreign Application Priority Data
Aug. 29, 2023 (KR) 10-2023-0113688

(51) Int. Cl. H10K 59/131

(52) U.S. Cl. CPC H10K 59/131

(57) ABSTRACT

A display device that includes a substrate; a circuit layer; and an element layer. The substrate may include a display area in which emission areas may be arranged, and a non-display area. In order to deliver data signals to data lines at side edges of the display area, bypass auxiliary lines are used that pass through central portions of the display area to allow for a reduced width of the sub area. A horizontal portion of these bypass auxiliary lines may pass over or under other data lines to reach the edge portion of the display. Therefore, a shielding auxiliary electrode may be disposed between the passed over data lines and the horizontal bypass auxiliary lines at locations where these other data lines overlap in a plan view the horizontal bypass auxiliary lines to reduce crosstalk between the horizontal bypass auxiliary lines and the data lines.

### CROSS-REFERENCE TO RELATED APPLICATIONS

This application claims priority under 35 U.S.C. § 119 from Korean Patent Application No. 10-2023-0113688 filed on Aug. 29, 2023 in the Korean Intellectual Property Office, the entire contents of which are incorporated herein by reference.

### BACKGROUND

### 1. Technical Field

The disclosure relates to a display device.

### 2. Description of the Related Art

With the advance of information-oriented society, more and more demands are being placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have relatively superior performance in power consumption, response speed, luminous efficiency, luminance, and wide viewing angle compared to other display devices.

A surface of the display device may be a display surface including a display area in which an image may be displayed and a non-display area that may be disposed at a periphery of the display area. Emission areas emitting light with respective luminances and colors may be arranged in the display area.

### SUMMARY

The display device may include light emitting elements disposed in emission areas, light emitting pixel drivers electrically connected to the light emitting elements, and data lines that transmit data signals to the light emitting pixel drivers.

Further, the display device may further include data supply lines electrically connected between the data lines and a display driving circuit to supply data signals.

Since the data supply lines may be disposed in the non-display area, as the display device becomes higher resolution or larger, the number and extension length of the data supply lines increase, so that the width of the non-display area may increase.

In view of the above, aspects of the disclosure provide a display device in which the rate of increase in the width of a non-display area due to the disposition of data supply lines may be reduced.

According to an aspect of the disclosure, there may be provided a display device that may include a substrate, a circuit layer disposed on the substrate, and an element layer disposed on the circuit layer. The substrate may include a main region and a sub-region protruding from a side of the main region, the man region comprising a display area in which emission areas may be arranged and a non-display area disposed around the display area. The element layer may include light emitting elements respectively disposed in the emission areas. The circuit layer may include light emitting pixel drivers respectively electrically connected to the light emitting elements, the light emitting pixel drivers may be arranged in a first direction and a second direction; data lines extending in the second direction, and transmitting data signals to the light emitting pixel drivers; first auxiliary lines extending in the first direction; and second auxiliary lines extending in the second direction, and respectively paired with the data lines.

The first auxiliary lines may include a first bypass auxiliary line electrically connected to a first data line disposed adjacent to an edge of the substrate in the first direction among the data lines. The second auxiliary lines may include a second bypass auxiliary line electrically connected to the first bypass auxiliary line, the second bypass auxiliary line may be paired with a second data line which may be spaced farther from the edge of the substrate than the first data line in the first direction among the data lines. The circuit layer may further include at least one shielding auxiliary electrode which overlaps an intersection area between the first bypass auxiliary line and at least one data line disposed between the second bypass auxiliary line and the first data line in the first direction among the data lines.

The at least one shielding auxiliary electrode may be disposed on a first insulating layer covering the first auxiliary lines. The data lines and the second auxiliary lines may be disposed on a second insulating layer covering the shielding auxiliary electrode. In a third direction in which the first insulating layer and the second insulating layer are stacked on each other, the at least one shielding auxiliary electrode may be disposed between the at least one data line and the first bypass auxiliary line.

The at least one shielding auxiliary electrode may extend in parallel with the first bypass auxiliary line, and may further overlap an intersection area between the first bypass auxiliary line and at least one second auxiliary line respectively paired with the at least one data line among the second auxiliary lines.

Each of the light emitting pixel drivers may include a first transistor electrically connected between a first node and a second node; a pixel capacitor electrically connected between a third node and a first power line transmitting a first power; a second transistor electrically connected between the data line and the first node; a third transistor electrically connected between the second node and the third node; a fourth transistor electrically connected between a gate initialization voltage line and the third node; a fifth transistor electrically connected between the first power line and the first node; a sixth transistor electrically connected between the second node and the fourth node; a seventh transistor electrically connected between a fourth node and an anode initialization voltage line transmitting an anode initialization voltage; and an eighth transistor electrically connected between a bias voltage line and the first node. The first node may be electrically connected to a first electrode of the first transistor. The second node may be electrically connected to a second electrode of the first transistor. The third node may be electrically connected to a gate electrode of the first transistor. The fourth node may be electrically connected to one of the light emitting elements. The first power line may extend in the second direction, may be arranged between first auxiliary lines adjacent in the first direction, and may be disposed on the second insulating layer. Among the at least one shielding auxiliary electrode, two shielding auxiliary electrodes adjacent in the first direction may be disposed adjacent to both sides of the first power line in the first direction.

The at least one shielding auxiliary electrode may be electrically connected to the first power line.

The circuit layer may further include a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first interlayer insulating layer covering the second gate conductive layer; a second semiconductor layer disposed on the first interlayer insulating layer; a third gate insulating layer covering the second semiconductor layer; a third gate conductive layer disposed on the third gate insulating layer; a second interlayer insulating layer covering the third gate conductive layer; a first source-drain conductive layer disposed on the second interlayer insulating layer; a first planarization layer covering the first source-drain conductive layer; a second source-drain conductive layer disposed on the first planarization layer; and a second planarization layer covering the second source-drain conductive layer. The first insulating layer may include the second interlayer insulating layer. The second insulating layer may include the first planarization layer.

The third gate conductive layer may include the first auxiliary lines. The first source-drain conductive layer may include the at least one shielding auxiliary electrode. The second source-drain conductive layer may include the data lines, the second auxiliary lines, and the first power line.

Each of the third gate conductive layer, the first source-drain conductive layer, and the second source-drain conductive layer has a multilayer structure that may include a main layer and at least one sub-layer disposed on at least one of both sides of the main layer. The main layer may include any one of molybdenum (Mo), aluminum (Al), chromium (Cr), gold (Au), nickel (Ni), neodymium (Nd), copper (Cu), and a combination thereof, and the at least one sub-layer may include titanium (Ti).

The display device may further include a display driving circuit disposed in the sub-region to supply the data signals to the data lines. The circuit layer may further include data supply lines extending from the display driving circuit to the display area to transmit data signals to the data lines. Among the data supply lines, a first data supply line which transmits the data signal of the first data line may be electrically connected to the second bypass auxiliary line. Among the data supply lines, a second data supply line which transmits the data signal of the second data line may be electrically connected (e.g., directly electrically connected) to the second data line.

The display device may further include a display driving circuit disposed in the sub-region. The circuit layer may further include demux circuits disposed in the sub-region to output the data signals to the data lines based on a data mux signal supplied from the display driving circuit; and data supply lines electrically connected between the demux circuits and the data lines to transmit the data signals to the data lines. Among the data supply lines, a first data supply line which transmits the data signal of the first data line may be electrically connected to the first bypass auxiliary line. Among the data supply lines, a second data supply line which transmits the data signal of the second data line may be electrically connected (e.g., directly electrically connected) to the second data line.

According to an aspect of the disclosure, there may be provided a display device that includes a substrate, a circuit layer disposed on the substrate, and an element layer disposed on the circuit layer. The substrate may include a main region and a sub-region protruding from a side of the main region, the main region may include a display area in which emission areas may be arranged and a non-display area disposed around the display area, and a sub-region protruding from a side of the main region. The element layer may include light emitting elements respectively disposed in the emission areas. The circuit layer may include light emitting pixel drivers respectively electrically connected to the light emitting elements, the light emitting pixel drivers may be arranged in a first direction and a second direction; data lines extending in the second direction to transmit data signals to the light emitting pixel drivers; a first bypass auxiliary line extending in a first direction and electrically connected to a first data line disposed adjacent to an edge of the substrate in the first direction among the data lines; a second bypass auxiliary line extending in the second direction and electrically connected to the first bypass auxiliary line, the second bypass auxiliary line may be paired with a second data line which may be spaced farther from the edge of the substrate than the first data line in the first direction among the data lines; and at least one shielding auxiliary electrode overlapping at least one data line which intersects the first bypass auxiliary line among the data lines.

The circuit layer may further include a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first interlayer insulating layer covering the second gate conductive layer; a second semiconductor layer disposed on the first interlayer insulating layer; a third gate insulating layer covering the second semiconductor layer; a third gate conductive layer disposed on the third gate insulating layer; a second interlayer insulating layer covering the third gate conductive layer; a first source-drain conductive layer disposed on the second interlayer insulating layer; a first planarization layer covering the first source-drain conductive layer; a second source-drain conductive layer disposed on the first planarization layer; and a second planarization layer covering the second source-drain conductive layer. The third gate conductive layer may include the first bypass auxiliary line. The first source-drain conductive layer may include the at least one shielding auxiliary electrode. The second source-drain conductive layer may include the data lines and the second bypass auxiliary line.

The at least one shielding auxiliary electrode may extend in parallel with the first bypass auxiliary line, and the at least one shielding auxiliary electrode may be disposed between the at least one data line and the first bypass auxiliary line in a third direction in which the second interlayer insulating layer and the first planarization layer are stacked on each other.

Each of the third gate conductive layer, the first source-drain conductive layer, and the second source-drain conductive layer has a multilayer structure comprising a main layer and at least one sub-layer disposed on at least one of both sides of the main layer. The main layer contains any one of molybdenum (Mo), aluminum (Al), chromium (Cr), gold (Au), nickel (Ni), neodymium (Nd), copper (Cu), and a combination thereof. The at least one sub-layer may include titanium (Ti).

The display device may further include a display driving circuit disposed in the sub-region. The circuit layer may further include demux circuits disposed in the sub-region to output the data signals to the data lines based on a data mux signal supplied from the display driving circuit; and data supply lines electrically connected between the demux circuits and the data lines, and transmitting the data signals to the data lines. Among the data supply lines, a first data supply line which transmits the data signal of the first data line may be electrically connected to the second bypass auxiliary line. Among the data supply lines, a second data supply line which transmits the data signal of the second data line may be electrically connected (e.g., directly electrically connected) to the second data line.

Each of the light emitting pixel drivers may include a first transistor electrically connected between a first node and a second node; a pixel capacitor electrically connected between a third node and a first power line transmitting a first power; a second transistor electrically connected between the data line and the first node; a third transistor electrically connected between the second node and the third node; a fourth transistor electrically connected between a gate initialization voltage line and the third node; a fifth transistor electrically connected between the first power line and the first node; a sixth transistor electrically connected between the second node and the fourth node; a seventh transistor electrically connected between a fourth node and an anode initialization voltage line transmitting an anode initialization voltage; and an eighth transistor electrically connected between a bias voltage line and the first node. The first node may be electrically connected to a first electrode of the first transistor. The second node may be electrically connected to a second electrode of the first transistor. The third node may be electrically connected to a gate electrode of the first transistor. The fourth node may be electrically connected to one of the light emitting elements. The at least one shielding auxiliary electrode may be electrically connected to the first power line.

The display device according to embodiments may include a substrate, a circuit layer, and an element layer. The circuit layer may include the light emitting pixel drivers that may be electrically connected to the light emitting elements of the element layer, respectively and may be arranged in a first direction and a second direction, the data lines may extend in the second direction and transmit data signals to the light emitting pixel drivers, a first bypass auxiliary line may extend in the first direction and may be electrically connected to a first data line disposed adjacent to the edge of the substrate in the first direction among the data lines, and a second bypass auxiliary line may extend in the second direction and may be paired with a second data line that may be spaced farther from the edge of the substrate than the first data line in the first direction among the data lines may be electrically connected to the first bypass auxiliary line.

The circuit layer may further include the data supply lines electrically connected between the data lines and the display driving circuit that supplies data signals. Among the data supply lines, a first data supply line may transmit a data signal to the first data line may be electrically connected to the first data line through the first bypass auxiliary line and the second bypass auxiliary line. Among the data supply lines, a second data supply line transmitting a data signal to the second data line may be electrically connected (e.g., directly electrically connected) to the second data line.

In this way, since the first data supply line does not extend to the first data line adjacent to the edge of the substrate, the extension length of the data supply lines may be reduced. Accordingly, the rate of increase in the width of the non-display area due to the disposition of the data supply lines may be reduced.

According to embodiments, the circuit layer may include at least one shielding auxiliary electrode that overlaps at least one data line that intersects the first bypass auxiliary line among the data lines.

At least one shielding auxiliary electrode may overlap the intersection area between at least one data line and the first bypass auxiliary line.

At least one shielding auxiliary electrode may be disposed between at least one data line and the first bypass auxiliary line in the third direction in which the insulating layers may be stacked.

In this way, the influence of the data signal of the first bypass auxiliary line on the data signal of at least one data line may be blocked by at least one shielding auxiliary electrode.

Accordingly, since the data signal of at least one data line may be stably maintained, deterioration of display quality due to the disposition of the first bypass auxiliary line may be prevented.

However, effects according to the embodiments of the disclosure may not be limited to those exemplified above and various other effects may be incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to embodiments;

FIG. 2 is a plan view illustrating the display device of FIG. 1;

FIG. 3 is a schematic cross-sectional view taken along line A-A′ of FIG. 2;

FIG. 4 is a schematic layout diagram illustrating part B of FIG. 2;

FIG. 5 is a schematic diagram of an equivalent circuit showing the light emitting pixel driver of FIG. 4 according to embodiments;

FIG. 6 is a schematic cross-sectional view showing the first transistor, second transistor, fourth transistor, sixth transistor, and light emitting element shown in FIG. 5;

FIG. 7 is an enlarged view showing part C of FIG. 6;

FIG. 8 is an enlarged view showing part D of FIG. 6;

FIG. 9 is an enlarged view showing part E of FIG. 6;

FIG. 10 is a plan view illustrating the substrate of FIG. 3 according to embodiments;

FIG. 11 is a schematic layout diagram showing part F of FIG. 10 according to an embodiment;

FIG. 12 is schematic a cross-sectional view taken along line G-G′ of FIG. 11;

FIG. 13 is a schematic layout diagram showing part F of FIG. 10 according to an embodiment;

FIG. 14 is a schematic diagram of an equivalent circuit of the demux of FIG. 13;

FIG. 15 is a timing diagram illustrating a data mux signal, a first demux control signal, and a second demux control signal of the demux input line illustrated in FIG. 14;

FIG. 16 is a plan view showing part H of FIG. 13 according to an embodiment; and

FIG. 17 is a schematic cross-sectional view taken along line I-I′ of FIG. 16.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis or first, second and third directions DR1, DR2, and DR3 are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

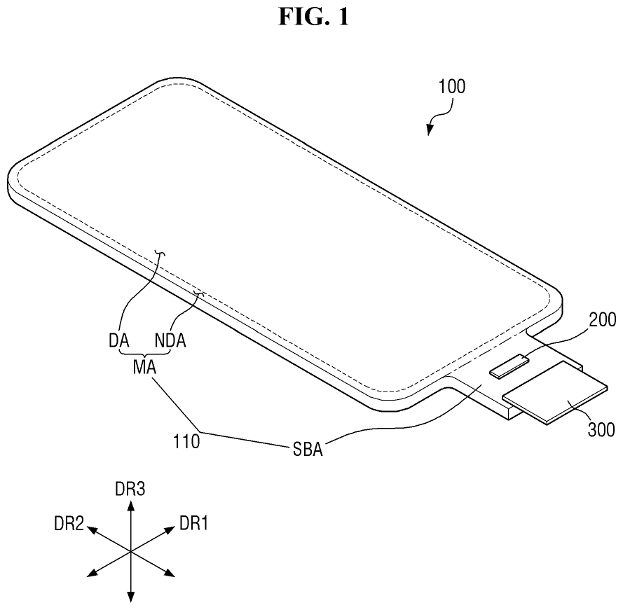

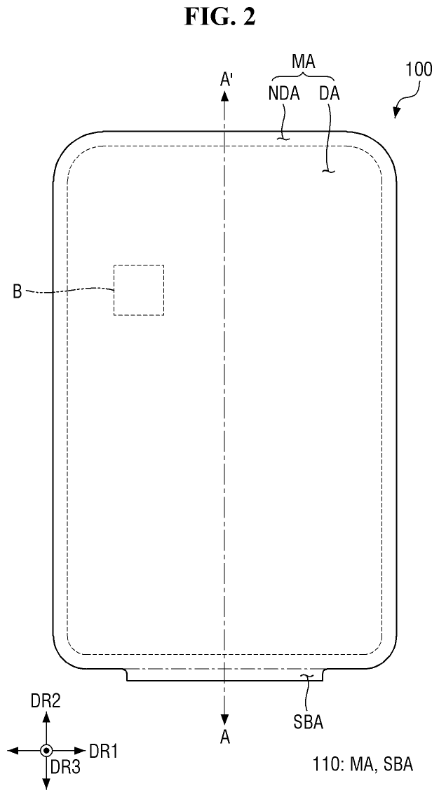

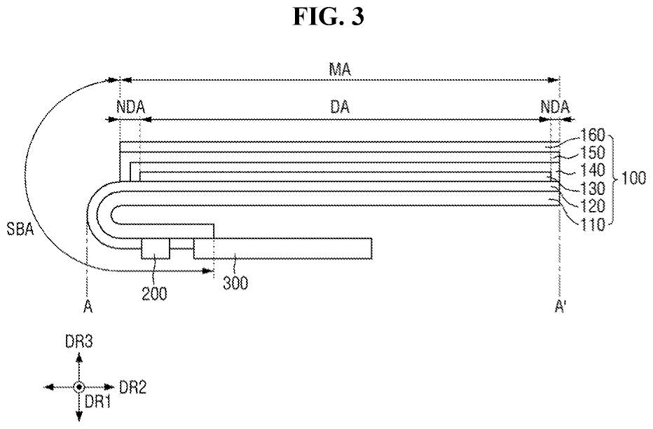

FIG. 1 is a perspective view illustrating a display device according to embodiments. FIG. 2 is a plan view illustrating the display device of FIG. 1. FIG. 3 is a schematic cross-sectional view taken along line A-A′ of FIG. 2.

Referring to FIGS. 1 and 2, a display device 100 is a device for displaying a moving image or a still image. The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the disclosure may not be limited thereto, and may be applied to a display device including an organic insulating material, an organic light emitting material, and a metal material.

The display device 100 may be formed to be approximately flat, but may not be limited thereto. For example, the display device 100 may include a curved portion formed at left and right ends and having a constant curvature or a varying curvature. The display device 100 may be formed flexibly so that it can be curved, bent, folded, or rolled.

As illustrated in FIGS. 1, 2 and 3, the display device 100 may include a substrate 110.

The substrate 110 may include a main region MA corresponding to a display surface of the display device 100 and a sub-region SBA protruding from a side of the main region MA.

As shown in FIG. 2, the main region MA may include a display area DA disposed at most of the center thereof, and a non-display area NDA disposed around the display area DA.

The display area DA may, in a plan view, be formed in a rectangular shape having short sides in a first direction DR1 and long sides in a second direction DR2 intersecting the first direction DR1. The corner where the short side in the first direction DR1 and the long side in the second direction DR2 meet may be rounded to have a curvature or may be right-angled. The planar shape of the display area DA may not be limited to the rectangular shape, and may be formed in another polygonal shape, a circular shape or an elliptical shape.

The non-display area NDA may be disposed at the edge of the main region MA to surround the display area DA.

The sub-region SBA may be a region protruding from a side of the non-display area NDA of the main region MA in the second direction DR2.

Since a part of the sub-region SBA may be transformed to be bent, another part of the sub-region SBA may be disposed on the rear surface of the display device 100.

FIGS. 2 and 3 illustrate the display device 100 with a part of the sub-region SBA in a bent state.

Referring to FIG. 3, the display device 100 according to embodiments includes the substrate 110, a circuit layer 120 disposed on the substrate 110, and an element layer 130 disposed on the circuit layer 120.

The display device 100 according to embodiments may further include an encapsulation layer 140 disposed on the element layer 130, and a touch sensor layer 150 disposed on the encapsulation layer 140.

Also, the display device 100 according to embodiments may further include a polarization layer 160 disposed on the touch sensor layer 150 to reduce reflection of external light.

The substrate 110 may be formed of an insulating material such as a polymer resin.

For example, the substrate 110 may be formed of polyimide. The substrate 110 may be a flexible substrate which can be bent, folded or rolled.

The substrate 110 may be formed of an insulating material such as glass or the like.

The substrate 110 may include the main region MA and the sub-region SBA. The main region MA may include the display area DA and the non-display area NDA.

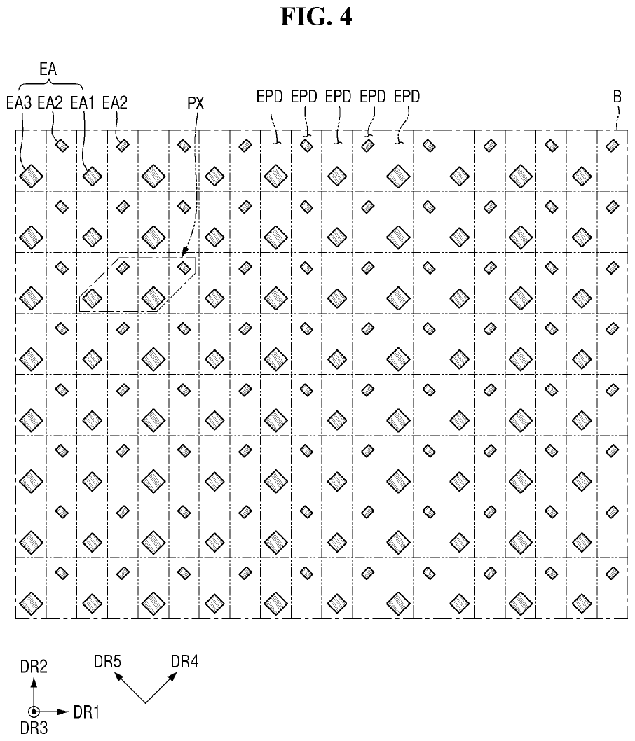

FIG. 4 is a schematic layout diagram illustrating part B of FIG. 2.

Referring to FIG. 4, the display area DA of the display device 100 according to embodiments may include the emission areas EA. The display area DA may further include a non-emission area disposed in a gap between the emission areas EA.

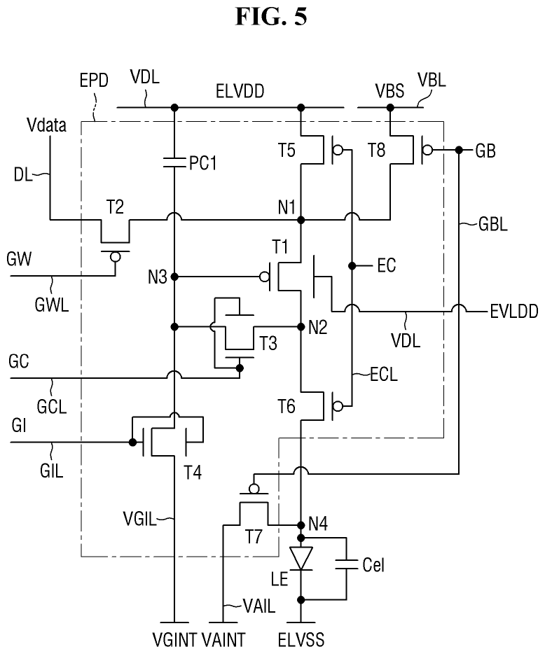

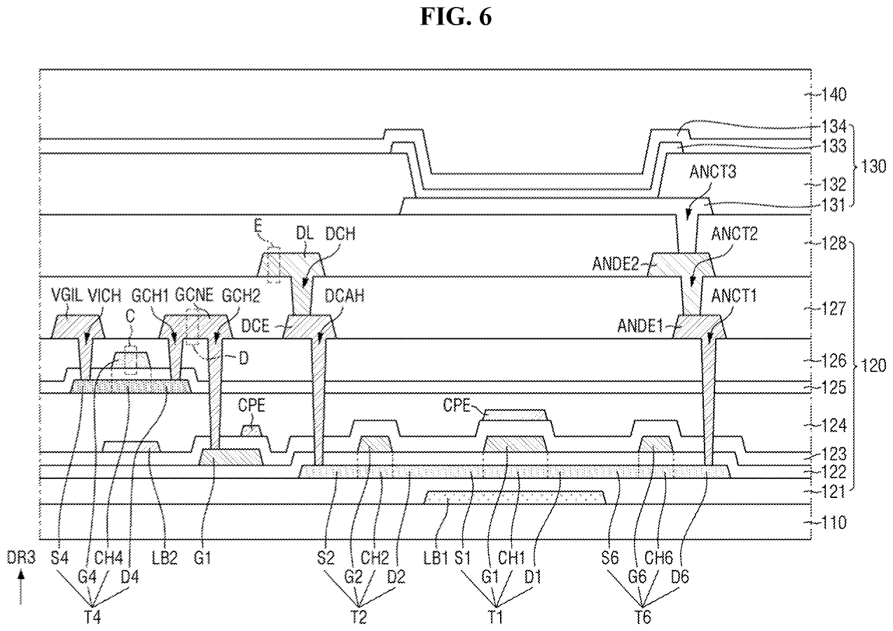

Light emitting pixel drivers EPD (or pixel circuit) respectively corresponding to the emission areas EA may be arranged in the display area DA in parallel with each other in the first direction DR1 and the second direction DR2. The light emitting pixel drivers EPD may be respectively electrically connected to light emitting elements LE (see FIGS. 5 and 6) of the element layer 130 respectively disposed in the emission areas EA.

The emission areas EA may have a rhombus planar shape or a rectangular planar shape. However, this may be only an example, and the planar shape of the emission areas EA according to an embodiment may not be limited to that illustrated in FIG. 4. In a plan view, the emission areas EA may have a polygonal shape such as a square, a pentagon, a hexagon, etc., or may have a circular or elliptical shape including the edge of a curve.

The emission areas EA may include first emission areas EA1 emitting light of a first color in a wavelength band, second emission areas EA2 emitting light of a second color in a wavelength band lower than that of the first color, and third emission areas EA3 emitting light of a third color in a wavelength band lower than that of the second color.

For example, the first color may be red having a wavelength band in a range of approximately 600 nm to approximately 750 nm. The second color may be green having a wavelength band in a range of approximately 480 nm to approximately 560 nm. The third color may be blue having a wavelength band in a range of approximately 370 nm to approximately 460 nm.

The first emission areas EA1 and the third emission areas EA3 may be alternately arranged in at least one of the first direction DR1 and the second direction DR2.

The second emission areas EA2 may be arranged side by side in at least one of the first direction DR1 and the second direction DR2.

The second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA.

In other words, the pixels PX may be a basic unit for displaying various colors including white with a luminance.

Each of the pixels PX may include at least one first emission area EA1, at least one second emission area EA2, and at least one third emission area EA3 that may be adjacent to each other. Accordingly, each of the pixels PX may display various colors through a mixture of the light emitted from the first emission area EA1, the second emission area EA2, and the third emission area EA3 that may be adjacent to each other.

FIG. 5 is a schematic diagram of an equivalent circuit of the light emitting pixel driver of FIG. 4 according to embodiments.

Referring to FIG. 5, one of the light emitting elements LE of the element layer 130 may be electrically connected between one of the light emitting pixel drivers EPD of the circuit layer 120 and a second power source ELVSS.

The anode electrode 131 (see FIG. 6) of the light emitting element LE may be electrically connected to the light emitting pixel driver EPD, and the cathode electrode 134 (see FIG. 6) of the light emitting element LE may be applied with a second power ELVSS lower than a first power ELVDD.

A capacitor Ce1 electrically connected in parallel with the light emitting element LE refers to a parasitic capacitance between the anode electrode 131 and the cathode electrode 134.

The circuit layer 120 may further include a first power line VDL for transmitting the first power ELVDD, a gate initialization voltage line VGIL for transmitting a gate initialization voltage VGINT, an anode initialization voltage line VAIL for transmitting an anode initialization voltage VAINT, and a bias voltage line VBL for transmitting a bias voltage VBS.

The circuit layer 120 may further include a scan write line GWL for transmitting a scan write signal GW, a scan initialization line GIL for transmitting a scan initialization signal GI, an emission control line ECL for transmitting an emission control signal EC, a gate control line GCL for transmitting a gate control signal GC, and a bias control line GBL for transmitting a bias control signal GB.

One light emitting pixel driver EPD of the circuit layer 120 may include a first transistor T1 configured to generate a driving current for driving the light emitting element LE, two or more transistors T2 to T8 electrically connected to the first transistor T1, and at least one capacitor PC1.

The first transistor T1 may be electrically connected in series with the light emitting element LE between the first power ELVDD and the second power ELVSS.

The first transistor T1 may be electrically connected between the first node N1 and the second node N2. The first node N1 may be electrically connected to the first electrode (e.g., source electrode) of the first transistor T1. The second node N2 may be electrically connected to the second electrode (e.g., drain electrode) of the first transistor T1.

In other words, the first electrode (e.g., the source electrode) of the first transistor T1 may be electrically connected to the first power line VDL through the fifth transistor T5. Further, the second electrode (e.g., the drain electrode) of the first transistor T1 may be electrically connected to the anode electrode of the light emitting element LE through the sixth transistor T6.

The first pixel capacitor PC1 may be electrically connected between the first power line VDL and a third node N3. The third node N3 may be electrically connected to the gate electrode of the first transistor T1.

The gate electrode of the first transistor T1 may be electrically connected to the first power line VDL through the first capacitor PC1.

Accordingly, the potential of the gate electrode of the first transistor T1 may be maintained at the voltage charged in the first power line VDL.

The second transistor T2 may be electrically connected between the data line DL and the first node N1.

In other words, the second transistor T2 may be electrically connected between the first electrode of the first transistor T1 and the data line DL. The second transistor T2 may be turned on by the scan write signal GW of the scan write line GWL.

The first electrode of the first transistor T1 may be electrically connected to the data line DL through the second transistor T2.

The fifth transistor T5 may be electrically connected between the first node N1 and the first power line VDL.

The sixth transistor T6 may be electrically connected between the second node N2 and the fourth node N4. The fourth node N4 may be electrically connected to the anode electrode of the light emitting element LE.

The fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the light emission control line ECL.

In case that the data signal Vdata of the data line DL may be transmitted to the first electrode of the first transistor T1 through the turned-on second transistor T2, the voltage difference between the gate electrode of the first transistor T1 and the first electrode of the first transistor T1 may be a difference voltage between the first power ELVDD and the data signal Vdata.

In case that the voltage difference between the gate electrode of the first transistor T1 and the first electrode of the first transistor T1, i.e., the gate-to-source voltage difference becomes equal to or greater than a threshold voltage, the first transistor T1 may be turned on, thereby generating a drain-source current in the first transistor T1 corresponding to the data signal Vdata.

In case that the fifth transistor T5 and the sixth transistor T6 are turned on, the first transistor T1 may be electrically connected in series with the light emitting element LE between the first power line VDL and the second power line VSL. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

The third transistor T3 may be electrically connected between the second node N2 and the third node N3. The third transistor T3 may be electrically connected between the gate electrode of the first transistor T1 and the second electrode of the first transistor T1. The third transistor T3 may be turned on by the gate control signal GC of the gate control line GCL.

Through the turned-on third transistor T3, the voltage difference between the second node N2 and the third node N3 may be initialized.

The fourth transistor T4 may be electrically connected between the gate initialization voltage line VGIL and the third node N3. The fourth transistor T4 may be electrically connected between the gate electrode of the first transistor T1 and the gate initialization voltage line VGIL. The fourth transistor T4 may be turned on by the scan initialization signal GI of the scan initialization line GIL.

The potential of the third node N3 may be initialized through the turned-on fourth transistor T4.

The third transistor T3 and the fourth transistor T4 may be provided as N-type MOSFETs.

The seventh transistor T7 may be electrically connected between the fourth node N4 and the anode initialization power line VAIL. The seventh transistor T7 may be electrically connected between the anode electrode of the light emitting element LE and the anode initialization voltage line VAIL. The seventh transistor T7 may be turned on by the bias control signal GB of the bias control line GBL.

The potential of the fourth node N4 may be initialized through the turned-on seventh transistor T7.

The eighth transistor T8 may be electrically connected between the first node N1 and the bias power line VBL. The eighth transistor T8 may be electrically connected between the first electrode of the first transistor T1 and the bias power line VBL. The eighth transistor T8 may be turned on by the bias control signal GB of the bias control line GBL.

The potential of the first node N1 may be initialized through the turned-on eighth transistor T8.

Among the first to eighth transistors T1 to T8, each of the transistors T1, T2, and T5 to T8 except for the third transistor T3 and the fourth transistor T4 may be implemented as a P-type MOSFET.

While each of the third transistor T3 and the fourth transistor T4 among the first to eighth transistors T1 to T8 included in the light emitting pixel driver EPD may be implemented as an N-type MOSFET, each of the remaining transistors T1, T2, and T5 to T8 except for these two may be implemented as a P-type MOSFET.

Accordingly, according to embodiments, the circuit layer 120 may include a first semiconductor layer and a second semiconductor layer.

The first semiconductor layer may include a channel portion, a first electrode portion, and a second electrode portion of each of the first transistor T1, the second transistor T2, the fifth transistor T5, the sixth transistor T6, the seventh transistor T7, and the eighth transistor T8. In each of the first transistor T1, second transistor T2, fifth transistor T5, sixth transistor T6, seventh transistor T7, and eighth transistor T8, the channel portion may overlap the gate electrode. Further, in each of the first transistor T1, the second transistor T2, the fifth transistor T5, the sixth transistor T6, the seventh transistor T7, and the eighth transistor T8, the first electrode portion and the second electrode portion may be electrically connected to both ends of the channel portion. The first electrode portion may become the first electrode, and the second electrode portion may become the second electrode.

The second semiconductor layer may include the channel portion, the first electrode portion, and the second electrode portion of each of the third transistor T3 and the fourth transistor T4. In each of the third transistor T3 and the fourth transistor T4, the channel portion may be disposed between the first gate electrode and the second gate electrode that overlap each other, and may overlap the first gate electrode and the second gate electrode. In each of the third transistor T3 and the fourth transistor T4, the first electrode portion and the second electrode portion may be electrically connected to both ends of the channel portion. The first electrode portion may become the first electrode, and the second electrode portion may become the second electrode.

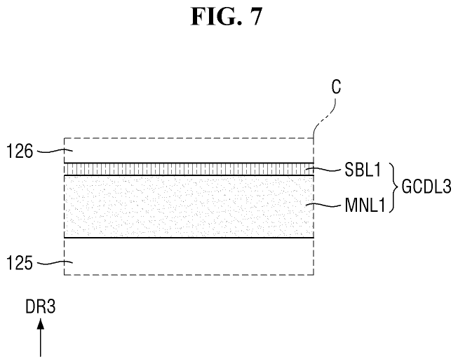

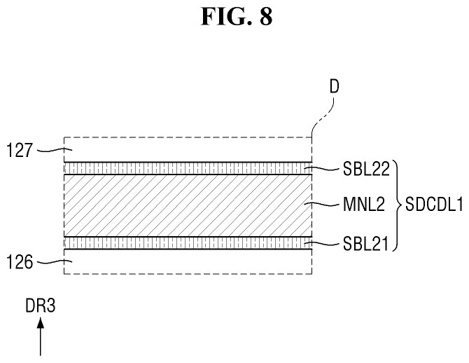

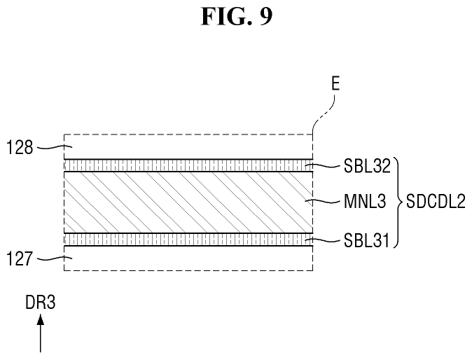

FIG. 6 is a schematic cross-sectional view showing the first transistor, second transistor, fourth transistor, sixth transistor, and light emitting element shown in FIG. 5. FIG. 7 is an enlarged view showing part C of FIG. 6. FIG. 8 is an enlarged view showing part D of FIG. 6. FIG. 9 is an enlarged view showing part E of FIG. 6.

Referring to FIG. 6, the display device 100 according to embodiments may include the substrate 110, the circuit layer 120 on the substrate 110, the element layer 130 on the circuit layer 120, and the encapsulation layer 140 on the element layer 130.

According to embodiments, the circuit layer 120 may include a first semiconductor layer CH1, S1, D1, CH2, S2, D2, CH6, S6, and D6 disposed on the substrate 110, a first gate insulating layer 122 covering the first semiconductor layer, a first gate conductive layer G1, G2, and G6 disposed on the first gate insulating layer 122, a second gate insulating layer 123 covering the first gate conductive layer, a second gate conductive layer CPE and LB2 disposed on the second gate insulating layer 123, a first interlayer insulating layer 124 covering the second gate conductive layer, a second semiconductor layer CH4, S4, and D4 disposed on the first interlayer insulating layer 124, a third gate insulating layer 125 covering the second semiconductor layer, a third gate conductive layer G4 disposed on the third gate insulating layer 125, a second interlayer insulating layer 126 covering the third gate conductive layer, a first source-drain conductive layer ANDE1, VGIL, GCNE, and DCE disposed on the second interlayer insulating layer 126, a first planarization layer 127 covering the first source-drain conductive layer, a second source-drain conductive layer DL and ANDE2 disposed on the first planarization layer 127, and a second planarization layer 128 covering the second source-drain conductive layer.

According to embodiments, the circuit layer 120 may further include a buffer layer 121 covering the substrate 110. The first semiconductor layer may be disposed on the buffer layer 121. The buffer layer 121 may cover a first light blocking layer LB1 on the substrate 110.

The first light blocking layer LB1 may overlap the channel portion CH1 of the first transistor T1.

Referring to FIGS. 7, 8, and 9, each of a third gate conductive layer GCDL3 (G4 in FIG. 6) on the third gate insulating layer 125, a first source-drain conductive layer SDCDL1 (ANDE1, VGIL, GCNE, and DCE in FIG. 6) on the second interlayer insulating layer 126, and a second source-drain conductive layer SDCDL2 (DL and ANDE2 in FIG. 6) on the first planarization layer 127 may have a multilayer structure including a main layer (MNL1 in FIG. 7, MNL2 in FIG. 8, and MNL3 in FIG. 9) and at least one sub-layer (SBL1 in FIG. 7, SBL21 and SBL22 in FIG. 8, and SBL31 and SBL32 in FIG. 9) disposed on at least one of both sides of the main layer.

The main layer (MNL1 in FIG. 7, MNL2 in FIG. 8, and MNL3 in FIG. 9) may include any one of molybdenum (Mo), aluminum (Al), chromium (Cr), gold (Au), nickel (Ni), neodymium (Nd), copper (Cu), or a combination thereof.

At least one sub-layer (SBL1 in FIG. 7, SBL21 and SBL22 in FIG. 8, and SBL31 and SBL32 in FIG. 9) may include titanium (Ti).

For example, as illustrated in FIG. 7, the third gate conductive layer GCDL3 on the third gate insulating layer 125 may have a double-layer structure including the first main layer MNL1 and the first sub-layer SBL1 on the first main layer MNL1. For example, the third gate conductive layer GCDL3 may have a double-layer structure of Ti/Al.

As illustrated in FIG. 8, the first source-drain conductive layer SDCDL1 on the second interlayer insulating layer 126 may have a triple-layer structure including the second main layer MNL2 and the second sub-layer SBL21 and the third sub-layer SBL22 disposed on both sides of the second main layer MNL2. For example, the first source-drain conductive layer SDCDL1 on the second interlayer insulating layer 126 may have a triple-layer structure of Ti/Al/Ti.

As illustrated in FIG. 9, the second source-drain conductive layer SDCDL2 on the first planarization layer 127 may have a triple-layer structure including the third main layer MNL3 and the fourth sub-layer SBL31 and the fifth sub-layer SBL32 disposed on both sides of the third main layer MNL3. For example, the second source-drain conductive layer SDCDL2 on the first planarization layer 127 may have a triple-layer structure of Ti/Al/Ti.

As previously described with reference to FIGS. 4 and 5, the circuit layer 120 may include the light emitting pixel drivers EPD electrically connected to the light emitting elements LE disposed in the emission areas EA, respectively, and wires that transmit various signals and voltages to the light emitting pixel drivers EPD. The light emitting pixel drivers EPD may include the first transistor T1 and two or more of the transistors T2 to T7 electrically connected to the first transistor T1.

As illustrated in FIG. 6, according to embodiments, the first transistor T1 may include a channel portion CH1, a source portion S1, and a drain portion D1 disposed in the first semiconductor layer on the substrate 110, and a gate electrode G1 disposed in the first gate conductive layer on the first gate insulating layer 122 covering the first semiconductor layer. The source portion S1 and the drain portion D1 may be electrically connected to both ends of the channel portion CH1. The source portion S1 and the drain portion D1 may be doped at a higher concentration than the channel portion CH1. The gate electrode G1 may overlap the channel portion CH1.

Similarly, the second transistor T2 may include a channel portion CH2, a source portion S2, and a drain portion D2 disposed in the first semiconductor layer on the substrate 110, and a gate electrode G2 disposed in the first gate conductive layer on the first gate insulating layer 122.

Further, the sixth transistor T6 may include a channel portion CH6, a source portion S6, and a drain portion D6 disposed in the first semiconductor layer on the substrate 110, and a gate electrode G6 disposed in the first gate conductive layer on the first gate insulating layer 122.

The source portion S2 of the second transistor T2 may be electrically connected to the data line DL through a data connection electrode DCE.

The data connection electrode DCE may be disposed the first source-drain conductive layer on the second interlayer insulating layer 126, and may be electrically connected to the source portion S2 of the second transistor T2 through a data auxiliary connection hole DCAH penetrating the second interlayer insulating layer 126, the third gate insulating layer 125, the first interlayer insulating layer 124, the second gate insulating layer 123, and the first gate insulating layer 122.

The data line DL may be disposed in the second source-drain conductive layer on the first planarization layer 127, and may be electrically connected to the data connection electrode DCE through a data connection hole DCH penetrating the first planarization layer 127.

The drain portion D2 of the second transistor T2 may be electrically connected to the source portion S1 of the first transistor T1.

The drain portion D1 of the first transistor T1 may be electrically connected to the source portion S6 of the sixth transistor T6.

The drain portion D6 of the sixth transistor T6 may be electrically connected to the anode electrode 131 through the first anode connection electrode ANDE1 and the second anode connection electrode ANDE2.

The first anode connection electrode ANDEL may be disposed in the first source-drain conductive layer, may be disposed on the second interlayer insulating layer 126 and may be electrically connected to the drain portion D6 of the sixth transistor T6 through a first anode contact hole ANCT1 penetrating the second interlayer insulating layer 126, the third gate insulating layer 125, the first interlayer insulating layer 124, the second gate insulating layer 123, and the first gate insulating layer 122.

The second anode connection electrode ANDE2 may be disposed in the second source-drain conductive layer, may be disposed on the first planarization layer 127 and may be electrically connected to the first anode connection electrode ANDE1 through a second anode contact hole ANCT2 penetrating the first planarization layer 127.

The anode electrode 131 may be disposed on the second planarization layer 128, and may be electrically connected to the second anode connection electrode ANDE2 through a third anode contact hole ANCT3 penetrating the second planarization layer 128.

According to embodiments, since the fifth transistor T5, the seventh transistor T7, and the eighth transistor T8 have substantially the same structure as the first transistor T1, the second transistor T2, and the sixth transistor T6, redundant description may be omitted below.

The first gate conductive layer on the first gate insulating layer 122 not only may include the gate electrode of each of the first transistor T1, the second transistor T2, the fifth transistor T5, the sixth transistor T6, the seventh transistor T7, and the eighth transistor T8, but also may further include the scan write line GWL electrically connected to the gate electrode G2 of the second transistor T2, and the bias control line GBL electrically connected to the gate electrode of the seventh transistor T7 and the gate electrode of the eighth transistor T8.

The pixel capacitor PC1 may be provided as an overlapping area between the gate electrode G1 of the first transistor T1 and the pixel capacitor electrode CPE.

The pixel capacitor electrode CPE may be disposed in the second gate conductive layer on the second gate insulating layer 123.

According to embodiments, in order to be provided as a different type from the first transistor T1, the second transistor T2, and the sixth transistor T6, the fourth transistor T4 may include a channel portion CH4, a source portion S4, and a drain portion D4 disposed in the second semiconductor layer on the first interlayer insulating layer 124, and a gate electrode G4 disposed in the third gate conductive layer on the third gate insulating layer 125.

The channel portion CH4 of the fourth transistor T4 may overlap a second light blocking layer LB2.

The second light blocking layer LB2 may be disposed in the second gate conductive layer on the second gate insulating layer 123.

According to embodiments, since the third transistor T3 has substantially the same structure as the fourth transistor T4, duplicate description will be omitted below.

The first source-drain conductive layer on the second interlayer insulating layer 126 may further include the gate initialization voltage line VGIL, the gate connection electrode GCNE, and the data connection electrode DCE.

The gate initialization voltage line VGIL may be electrically connected to the source portion S4 of the fourth transistor T4 through an initialization connection hole VICH.

The gate connection electrode GCNE may be electrically connected to the drain portion D4 of the fourth transistor T4 through a first gate connection hole GCH1, and may be electrically connected to the gate electrode G1 of the first transistor T1 through a second gate connection hole GCH2.

The data line DL may be disposed in the second source-drain conductive layer on the first planarization layer 127.

The element layer 130 may include the light emitting elements LE disposed on the second planarization layer 128 and respectively corresponding to the emission areas EA.

Each of the light emitting elements LE may include an anode electrode 131 and a cathode electrode 134 facing each other, and a light emitting layer 133 disposed therebetween.

Each of the light emitting elements LE may further include a first common layer disposed between the anode electrode 131 and the light emitting layer 133, and a second common layer disposed between the light emitting layer 133 and the cathode electrode 134.

The element layer 130 may include the anode electrodes 131 respectively corresponding to the emission areas EA, a pixel defining layer 132 corresponding to a non-emission area between the emission areas EA and covering the edge of the anode electrode 131, and the cathode electrode 134 disposed on the light emitting layers 133 and the pixel defining layer 132.

The anode electrode 131 may be disposed in each of the emission areas EA and may be electrically connected to one light emitting pixel driver EPD of the circuit layer 120. This anode electrode 131 may be referred to as a pixel electrode.

The anode electrode 131 may be electrically connected to the second anode connection electrode ANDE2 through a third anode contact hole ANCT3 penetrating the second planarization layer 128.

The light emitting layer 133 may be formed of an organic light emitting material that converts electron-hole pairs into light.

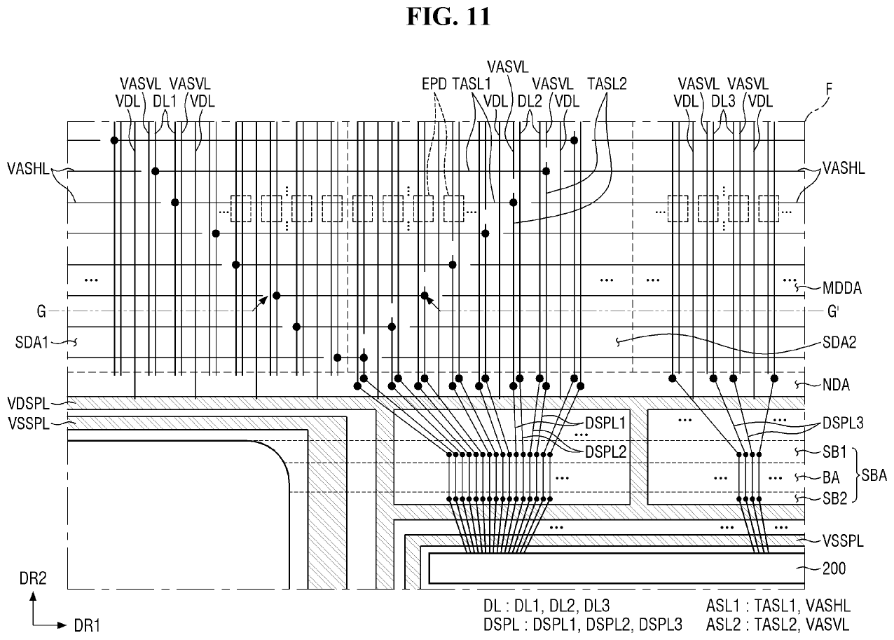

The cathode electrode 134 may be disposed in the display area DA including the emission areas EA. The cathode electrode 134 may be electrically connected to a second power supply line VSSPL (see FIG. 11) that transmits the second power ELVSS. The cathode electrode 134 may be referred to as a common electrode.

The encapsulation layer 140 may be disposed on the circuit layer 120 and cover the element layer 130.

As an example, the encapsulation layer 140 may include a first encapsulation layer disposed on the element layer 130 and made of an inorganic insulating material, a second encapsulation layer disposed on the first encapsulation layer, overlapping the element layer 130, and made of an organic insulating material, and a third encapsulation layer disposed on the first encapsulation layer, covering the second encapsulation layer, and made of an inorganic insulating material.

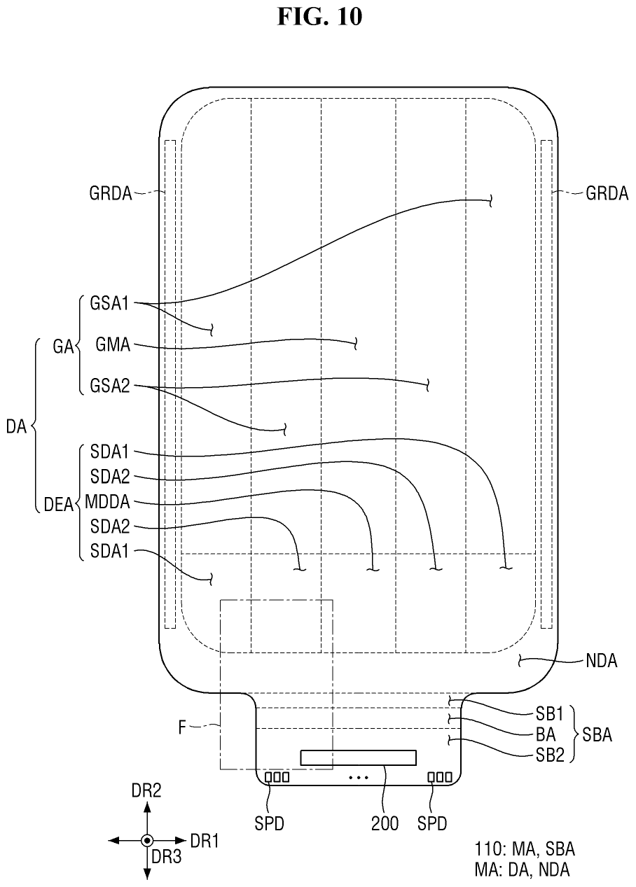

FIG. 10 is a plan view illustrating the substrate of FIG. 3 according to embodiments.

Referring to FIG. 10, the substrate 110 of the display device 100 according to embodiments includes the main region MA corresponding to the display surface, and the sub-region SBA protruding from a side of the main region MA.

The main region MA may include the display area DA disposed at most of the center, and the non-display area NDA disposed at the periphery to surround the display area DA.

The display area DA may include a bypass area DEA disposed on a side adjacent to the sub-region SBA, and a general area GA disposed in the remaining area excluding the bypass area DEA.

The bypass area DEA may include a bypass middle area MDDA disposed at the center in the first direction DR1, a first bypass side area SDA1 parallel to the bypass middle area MDDA in the first direction DR1 and in contact with the non-display area NDA, and a second bypass side area SDA2 disposed between the bypass middle area MDDA and the first bypass side area SDA1.

The first bypass side area SDA1 may be disposed adjacent to the bent corner of the substrate 110 as compared to the bypass middle area MDDA and the second bypass side area SDA2.

The first bypass side area SDA1 and the second bypass side area SDA2 may be disposed between the bypass middle area MDDA and the non-display area NDA on both sides of the bypass middle area MDDA in the first direction DR1.

The general area GA may include a general middle area GMA extended to the bypass middle area MDDA of the bypass area DEA in the second direction DR2, a first general side area GSA1 extended to the first side area SDA1 of the bypass area DEA in the second direction DR2, and a second general side area GSA2 extended to the second side area SDA2 of the bypass area DEA in the see bond direction DR2.

The non-display area NDA may include a gate driving circuit area GDRA where a gate driving circuit may be disposed.

The gate driving circuit area GDRA may be disposed in a portion of the non-display area NDA adjacent to at least one side of the display area DA in the first direction DR1.

The gate driving circuit of the gate driving circuit area GDRA may sequentially transmit gate signals to gate lines. Here, the gate lines may include the scan write line GWL (see FIG. 5) that transmits the scan write signal GW (see FIG. 5), the scan initialization line GIL (see FIG. 5) that transmits the scan initialization signal GI (see FIG. 5), the gate control line GCL (see FIG. 5) that transmits the gate control signal GC (see FIG. 5), the bias control line GBL (see FIG. 5) that transmits the bias control signal GB (see FIG. 5), and the emission control line ECL (see FIG. 5) that transmits the emission control signal EC (see FIG. 5).

The sub-region SBA may include a bending region BA that may be transformed into a bent shape, a first sub-region SB1 disposed between a side of the bending region BA and the main region MA, and a second sub-region SB2 extending to the another side of the bending region BA.

In case that the bending region BA may be transformed into a bent shape, the second sub-region SB2 may be disposed below the substrate 110 and may overlap the main region MA.

The display driving circuit 200 may be disposed in the second sub-region SB2.

The signal pads SPD bonded to the circuit board 300 may be disposed at an edge of the second sub-region SB2.

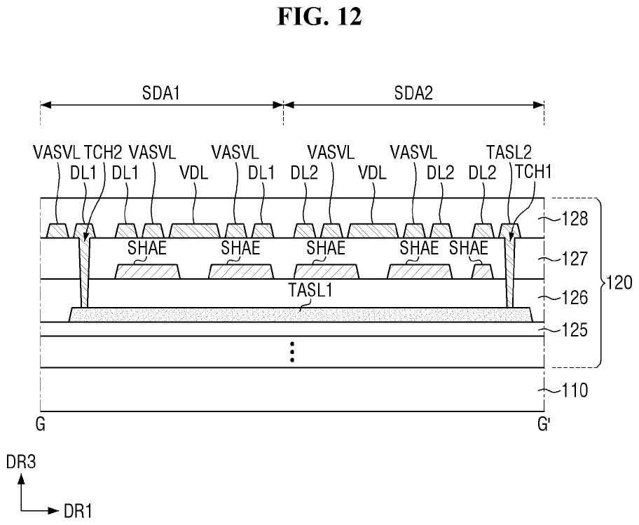

FIG. 11 is a layout diagram showing part F of FIG. 10 according to an embodiment. FIG. 12 is a cross-sectional view taken along line G-G′ of FIG. 11.

Referring to FIG. 11, the circuit layer 120 of the display device 100 according to embodiments may include the light emitting pixel drivers EPD electrically connected to the light emitting elements LE of the element layer 130, respectively and arranged in the first direction DR1 and the second direction DR2, the data lines DL extending in the second direction DR2 and transmitting the data signal Vdata (see FIG. 5) to the light emitting pixel drivers EPD, a first bypass auxiliary line TASL1 electrically connected to a first data line DL1 disposed adjacent to the edge of the substrate 110 in the first direction DR1 among the data lines DL and extending in the first direction DR1, and a second bypass auxiliary line TASL2 paired with a second data line DL2, which may be spaced farther from the edge of the substrate 110 than the first data line DL1 in the first direction DR1 among the data lines DL, electrically connected to the first bypass auxiliary line TASL1, and extending in the second direction DR2.

The first bypass auxiliary line TASL1 may be some of first auxiliary lines ASL1 extending in the first direction DR1.

The first auxiliary lines ASL1 may overlap the light emitting pixel drivers EPD of the display area DA. The number of first auxiliary lines ASL1 may be the number of columns each including the emission areas EA arranged in the first direction DR1.

The first bypass auxiliary line TASL1 may be disposed between the first data line DL1 and the second bypass auxiliary line TASL2. Accordingly, since both ends of the first bypass auxiliary line TASL1 may be disposed in the display area DA, in order to lower the visibility of both ends of the first bypass auxiliary line TASL1, the first auxiliary line ASL1 may further include not only the first bypass auxiliary line TASL1 but also power auxiliary horizontal lines VASHL.

The second bypass auxiliary line TASL2 may be some of second auxiliary lines ASL2 that extend in the second direction DR2 and may be paired with the data lines DL, respectively.

The data lines DL and the second auxiliary lines ASL2 may be alternately arranged in pairs in the first direction DR1.

The second bypass auxiliary line TASL2 may be disposed between the first bypass auxiliary line TASL1 and the non-display area NDA. Accordingly, since an end of the second bypass auxiliary line TASL2 may be disposed in the display area DA, in order to lower the visibility of the end of the second bypass auxiliary line TASL2, the second auxiliary line ASL2 may further include not only the second bypass auxiliary line TASL2 but also the power auxiliary vertical lines VASVL.

The power auxiliary horizontal lines VASHL and the power auxiliary vertical lines VASVL may transmit at least one of the first power ELVDD, the second power ELVSS, or the initialization voltage VINT. As an example, the power auxiliary horizontal lines VASHL and the power auxiliary vertical lines VASVL may transmit the second power ELVSS. In another example, some of the power auxiliary horizontal lines VASHL and some of the power auxiliary vertical lines VASVL may transmit the secondary power ELVSS, and some others of the power auxiliary horizontal lines VASHL and some others of the power auxiliary vertical lines VASVL may transmit the initialization voltage VINT.

According to embodiments, the data lines DL may include the first data line DL1 disposed in the first bypass side area SDA1 in contact with the non-display area NDA in the first direction DR1, and the second data line DL2 disposed in the second bypass side area SDA2 between the first bypass side area SDA1 and the bypass middle area MDDA in the first direction DR1.

According to an embodiment, the circuit layer 120 may further include data supply lines DSPL extending from the display driving circuit 200 to the display area DA and transmitting the data signal Vdata of the data lines DL.

The data supply lines DSPL may include a first data supply line DSPL1 that transmits the data signal of the first data line DL1, and a second data supply line DSPL2 that transmits the data signal of the second data line DL2.

The data supply lines DSPL may extend to the second bypass side area SDA2 and the bypass middle area MDDA.

Accordingly, the second data supply line DSPL2, which transmits the data signal of the second data line DL2, may extend to the second bypass side area SDA2 and may be electrically connected (e.g., directly electrically connected) to the second data line DL2.

On the other hand, the first data supply line DSPL1, which transmits the data signal of the first data line DL1, may extend to the second bypass auxiliary line TASL2 of the second bypass side area SDA2, and may be electrically connected to the first data line DL1 through the second bypass auxiliary line TASL2 and the first bypass auxiliary line TASL1.

In this way, since the first data supply line DSPL1 extends not to the first data line DL1 of the first bypass side area SDA1 but to the second bypass auxiliary line TASL2 of the second bypass side area SDA2, the extension length of the first data supply line DSPL1 may be shortened. As a result, the width of the area required for the arrangement of the data supply lines DSPL may be reduced, so that the width of the non-display area NDA may be reduced.

In addition, since the data supply lines DSPL may not be disposed in a portion of the non-display area NDA located between the bent corner of the substrate 110 and the first bypass side area SDA1, the width of the non-display area NDA can be further reduced.

The data lines DL may further include a third data line DL3 disposed in the bypass middle area MDDA. The data supply lines DSPL may further include a third data supply line DSPL3 that transmits the data signal of the third data line DL3.

The third data supply line DSPL3 may extend to the bypass middle area MDDA, and may be electrically connected (e.g., directly electrically connected) to the third data line DL3.

The circuit layer 120 may further include a first power supply line VDSPL and a second power supply line VSSPL that respectively transmit the first power ELVDD and the second power ELVSS for driving the light emitting elements LE.

The first power supply line VDSPL and the second power supply line VSSPL may be disposed in the non-display area NDA and may extend to the sub-region SBA.

The first power supply line VDSPL may be electrically connected to a first power pad for transmitting the first power ELVDD among the signal pads SPD disposed in the second sub-region SB2.

The second power supply line VSSPL may be electrically connected to a second power pad for transmitting the second power ELVSS among the signal pads SPD disposed in the second sub-region SB2.

The power auxiliary horizontal lines VASHL may be electrically connected to the second power supply line VSSPL.

The power auxiliary vertical lines VASVL may be electrically connected to the power auxiliary horizontal lines VASHL and the second power supply line VSSPL.

According to embodiments, the circuit layer 120 may further include the first power lines VDL electrically connected between the light emitting pixel drivers EPD and the first power supply line VDSPL.

The first power lines VDL may be disposed between two second auxiliary lines ASL2 adjacent to each other in the first direction DR1.

Referring to FIG. 12, the circuit layer 120 of the display device 100 according to embodiments may further include at least one shielding auxiliary electrode SHAE that overlaps at least one data line that intersects the first bypass auxiliary line TASL1 among the data lines DL.

At least one shielding auxiliary electrode SHAE may overlap the intersection area (i.e., overlapping area in a plan view) between the first bypass auxiliary line TASL1 and at least one data line disposed between the second bypass auxiliary line TASL2 and the first data line DL1 in the first direction DR1 among the data lines DL. It is to be understood that the term “intersection area” in no way infers electrical connection, but rather infers an area where the at least one data line and the first bypass auxiliary line TASL1 overlap each other in a plan view.

According to embodiments, at least one shielding auxiliary electrode SHAE may be disposed on the first insulating layer (e.g., the second interlayer insulating layer 126) covering the first auxiliary lines ASL1, and the data lines DL and the second auxiliary lines ASL2 may be disposed on the second insulating layer (e.g., the first planarization layer 127) covering at least one shielding auxiliary electrode SHAE.

The third gate conductive layer GCDL3 (see FIG. 7) disposed on the third gate insulating layer 125 may include the first auxiliary lines ASL1, the first source-drain conductive layer SDCDL1 (see FIG. 8) on the second interlayer insulating layer 126 may include at least one shielding auxiliary electrode SHAE, and the second source-drain conductive layer SDCDL2 (see FIG. 9) on the first planarization layer 127 may include the data lines DL and the second auxiliary lines ASL2.

The first insulating layer covering the first auxiliary lines ASL1 may include the second interlayer insulating layer 126, and the second insulating layer covering at least one shielding auxiliary electrode SHAE may include the first planarization layer 127.

Accordingly, in the third direction DR3 in which the first insulating layer 126 and the second insulating layer 127 are stacked on each other, at least one shielding auxiliary electrode SHAE may be disposed between at least one data line and the first bypass auxiliary line TASL1.

Further, in order to lower the wiring resistance of the first auxiliary line ASL1, the third gate conductive layer GCDL3 (see FIG. 7) on the third gate insulating layer 125 may be provided in a double-layer structure in which the first main layer MNL1 (see FIG. 7) and the first sub-layer SBL1 (see FIG. 7) are stacked on each other.

At least one shielding auxiliary electrode SHAE may correspond one-to-one to at least one data line disposed between the first data line DL1 and the second bypass auxiliary line TASL2 in the first direction DR1.

However, this may be merely an example, and in case that there is no possibility of an electrical short circuit, at least one shielding auxiliary electrode SHAE may extend in the first direction DR1 in parallel to the first bypass auxiliary line TASL1, and may correspond to two or more data lines that may be adjacent to each other in at least one data line disposed between the first data line DL1 and the second bypass auxiliary line TASL2.

As illustrated in FIG. 12, at least one shielding auxiliary electrode SHAE may extend in the first direction DR1 in parallel to the first bypass auxiliary line TASL1, and may further overlap the intersection area between the first bypass auxiliary line TASL1 and at least one second auxiliary line that may be respectively paired with at least one data line among the second auxiliary lines ASL2.

As illustrated in FIG. 11, the first auxiliary lines ASL1 may extend in the first direction DR1 between the first bypass side area SDA1 and the second bypass side area SDA2, and may include the first bypass auxiliary lines TASL1 arranged in the second direction DR2.

According to embodiments, in order to readily prevent electrical short circuit defects between the first bypass auxiliary lines TASL1, the shorter the first bypass auxiliary lines TASL1 may be, the more adjacently (or closer together) the first bypass auxiliary lines TASL1 may be disposed to the sub-region SBA in the second direction DR2.

Accordingly, at least one second auxiliary line disposed between the first data line DL1 and the second bypass auxiliary line TASL2 in the first direction DR1 among the second auxiliary lines ASL2 may be the power auxiliary vertical line VASVL.

As illustrated in FIG. 12, the second bypass auxiliary line TASL2 may be electrically connected to the first bypass auxiliary line TASL1 through a first bypass connection hole TCH1.

The first data line DL1 may be electrically connected to the first bypass auxiliary line TASL1 through a second bypass connection hole TCH2.

Each of the first bypass connection hole TCH1 and the second bypass connection hole TCH2 may penetrate the first planarization layer 127 and the second interlayer insulating layer 126.

In this way, according to an embodiment, at least one shielding auxiliary electrode SHAE overlapping at least one data line that intersects the first bypass auxiliary line TASL1 among the data lines DL may be disposed between the first bypass auxiliary line TASL1 and at least one data line.

Accordingly, the influence of the data signal that passes through the first bypass auxiliary line TASL1 on the data signal transmitting through at least one data line may be shielded by at least one shielding auxiliary electrode SHAE. Accordingly, the data signal of at least one data line may be maintained relatively stable without distortion due to coupling with the data signal of the first bypass auxiliary line TASL1. Accordingly, deterioration of display quality due to the disposition of the first bypass auxiliary line TASL1 intersecting at least one data line may be prevented.

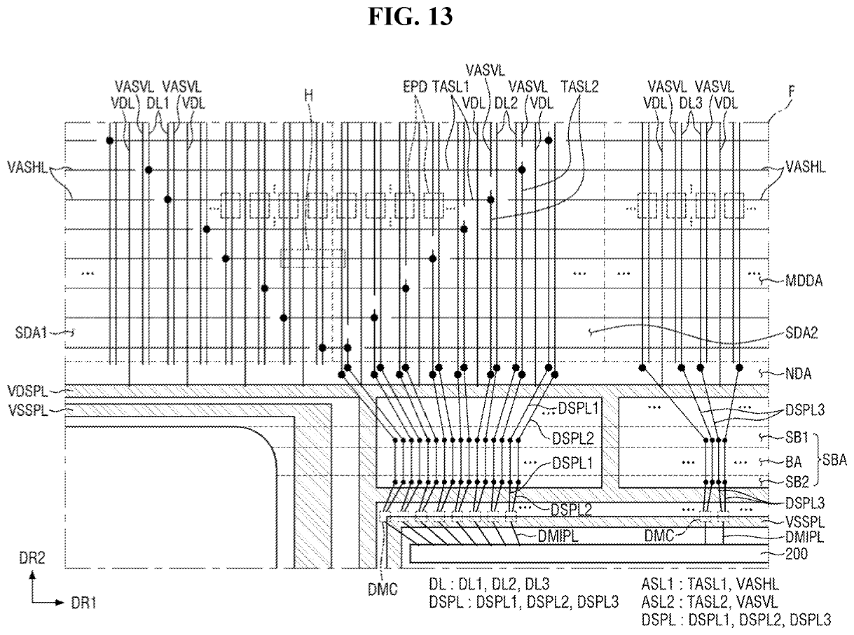

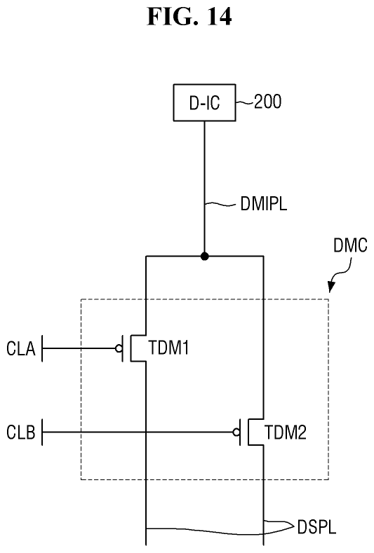

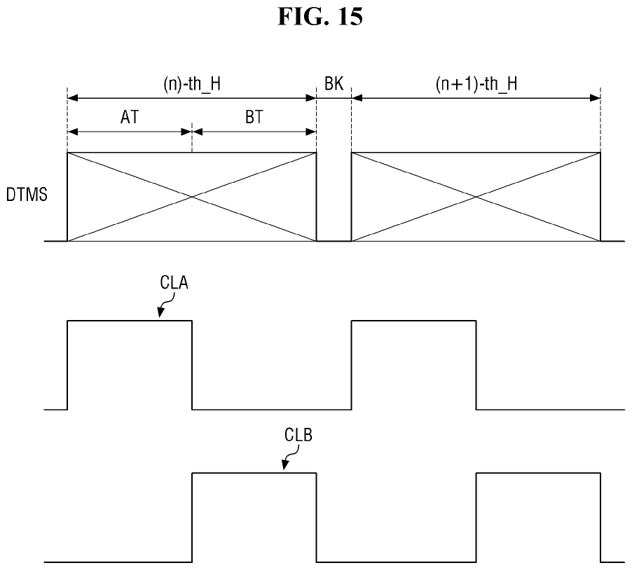

FIG. 13 is a layout diagram showing part F of FIG. 10 according to an embodiment. FIG. 14 is a schematic diagram of an equivalent circuit of the demux circuit of FIG. 13. FIG. 15 is a timing diagram illustrating a data mux signal, a first demux control signal, and a second demux control signal of the demux input line illustrated in FIG. 14.

The display device 100 of an embodiment illustrated in FIG. 13 is substantially the same as an embodiment illustrated in FIG. 11, except the fact that the circuit layer 120 further includes demux circuits DMC output the data signals to the data lines DL based on the data mux signal supplied from the display driving circuit 200 and the fact that the data supply lines DSPL may be electrically connected between the demux circuits DMC and the data lines DL, and thus redundant descriptions will be omitted below.

The demux circuits DMC may be disposed in the sub-region SBA.

According to an embodiment, the demux circuits DMC may be disposed in the second sub-region SB2.

The circuit layer 120 may further include demux input lines DMIPL electrically connected between the display driving circuit 200 and the demux circuits DMC.

The demux input lines DMIPL may transmit the data mux signal supplied from the display driving circuit 200 to the demux circuits DMC.

The data supply lines DSPL may extend from the demux circuits DMC to the second bypass side area SDA2 and the bypass middle area MDDA.

Among the data supply lines DSPL, the first data supply line DSPL1 transmitting the data signal of the first data line DL1 may extend to the second bypass side area SDA2 and may be electrically connected to the second bypass auxiliary line TASL2. The first data supply line DSPL1 may be electrically connected to the first data line DL1 of the first bypass side area SDA1 through the first bypass auxiliary line TASL1 and the second bypass auxiliary line TASL2.

Among the data supply lines DSPL, the second data supply line DSPL2 transmitting the data signal of the second data line DL2 may extend to the second bypass side area SDA2 and may be electrically connected (e.g., directly electrically connected) to the second data line DL2.

Among the data supply lines DSPL, the third data supply line DSPL3 transmitting the data signal of the third data line DL3 may extend to the bypass middle area MDDA and may be electrically connected (e.g., directly electrically connected) to the third data line DL3.

Each of the demux circuits DMC may be electrically connected to two or more data supply lines DSPL.

As an example, each of the demux circuits DMC may include two output terminals.

The output terminals of a demux circuit DMC of the demux circuits DMC may be electrically connected to a first data supply line DSPL1 and a second data supply line DSPL2.

As another example, the output terminals of a demux circuit DMC of the demux circuits DMC may be electrically connected to two first data supply lines DSPL1, or may be electrically connected to two second data supply lines DSPL2.

The output terminals of another demux circuit DMC of the demux circuits DMC may be electrically connected to two third data supply lines DSPL3.

Referring to FIG. 14, each of the demux circuits DMC may include two or more demux transistors TDM1 and TDM2 electrically connected between each of two or more data supply lines DSPL and a demux input line DMIPL.

As an example, each of the demux circuits DMC may include the first demux transistor TDM1 turned on by a first demux control signal CLA, and the second demux transistor TDM2 turned on by a second demux control signal CLB.

Referring to FIG. 15, the display driving circuit 200 may output a data mux signal DTMS during each of the image frame periods (n)-th_H and (n+1)-th_H (where n may be a natural number of 1 or more). The data mux signal DTMS may include a first data signal and a second data signal corresponding to each of the image frame periods (n)-th_H and (n+1)-th_H (where n may be a natural number of 1 or more).

The first data signal of the data mux signal DTMS may be output to a data supply line electrically connected to the output terminal of the demux circuit DMC through a first demux transistor TDM1 turned on by a first demux control signal CLA during a first period AT in each of the image frame periods (n)-th_H and (n+1)-th_H.

The second data signal of the data mux signal DTMS may be output to another data supply line electrically connected to the output terminal of the demux circuit DMC through a second demux transistor TDM2 turned on by a second demux control signal CLB during a second period BT after the first period AT in each of the image frame periods (n)-th_H and (n+1)-th_H.

In this way, according to an embodiment, since the data signals of the data lines DL may be supplied in a time division manner using the demux circuits DMC, some of the data signals supplied during the first period AT may be readily distorted.

In particular, in the first bypass side area SDA1 and the second bypass side area SDA2, a data signal may be supplied to a part of at least one data line that intersects the first bypass auxiliary line TASL1 during the first period AT, and thus may be relatively greatly affected by the data signal transmitted through the first bypass auxiliary line TASL1.

However, the circuit layer 120 of the display device 100 according to an embodiment may include at least one shielding auxiliary electrode SHAE disposed between at least one data line and the first bypass auxiliary line TASL1, so that distortion of the data signal supplied during the first period AT may be reduced.

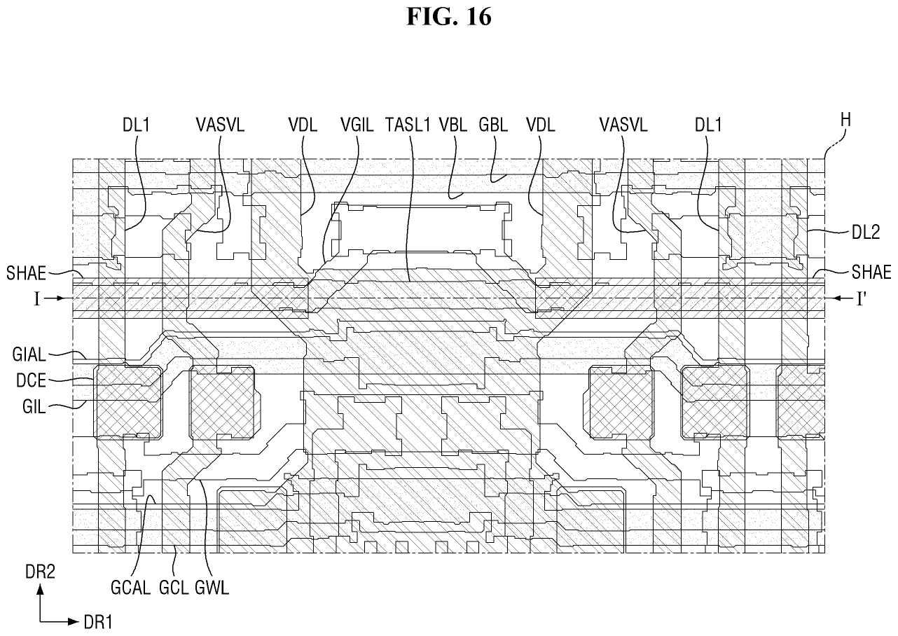

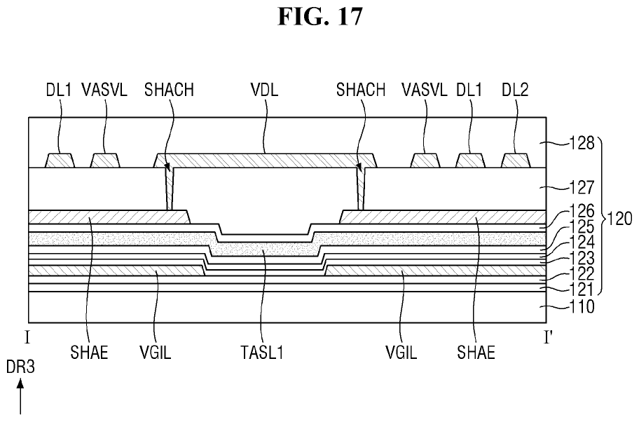

FIG. 16 is a plan view showing part H of FIG. 13 according to an embodiment. FIG. 17 is a schematic cross-sectional view taken along line I-I′ of FIG. 16.

Referring to FIGS. 16 and 17, the data lines DL (DL1, DL2), the second auxiliary lines ASL2 (VASVL), and the first power line VDL may extend in the second direction DR2 and may be disposed on a same layer.

The first power line VDL may be disposed between the second auxiliary lines ASL2 (VASVL) in the first direction DR1.

A second auxiliary line ASL2 (VASVL) of the two second auxiliary lines ASL2 (VASVL) disposed on both sides of the first power line VDL in the first direction DR1 may be adjacent to the data line DL (DL1, DL2) paired therewith on a side (e.g., the left side of FIG. 16) in the first direction DR1. Further, another second auxiliary line ASL2 (VASVL) of the two second auxiliary lines ASL2 (VASVL) disposed on both sides of the first power line VDL in the first direction DR1 may be adjacent to the data line DL (DL1, DL2) paired therewith on another side (e.g., the right side of FIG. 16) in the first direction DR1.

The first bypass auxiliary line TASL1 may extend in the first direction DR1.

Further, each of the bias control line GBL, the bias power line VBS, the gate initialization voltage line VGIL, the scan initialization line GIL, the scan write line GWL, and the gate control line GCL may extend in the first direction DR1.

The bias control line GBL and the bias power line VBS may be adjacent to each other and may overlap each other at least partially.

As an example, the bias control line GBL may be disposed in the first gate conductive layer on the first gate insulating layer 122.

Further, the bias power line VBS may be disposed in the second gate conductive layer on the second gate insulating layer 123. However, this may be merely an example and may be changed as needed depending on the circuit design.

The gate initialization voltage line VGIL may be adjacent to the bias control line GBL on a side (e.g., the lower side of FIG. 16) in the second direction DR2.

As illustrated in FIGS. 16 and 17, the first auxiliary line ASL1 including the first bypass auxiliary line TASL1 may overlap a part of the gate initialization voltage line VGIL.

As an example, the gate initialization voltage line VGIL may be disposed in the first gate conductive layer on the first gate insulating layer 122.

According to embodiments, the first auxiliary line ASL1 including the first bypass auxiliary line TASL1 may be disposed in the second gate conductive layer on the second gate insulating layer 123.

According to embodiments, the circuit layer 120 may include at least one shielding auxiliary electrode SHAE disposed in the intersection area between at least one data line DL1, DL2 and the first bypass auxiliary line TASL1.

The first auxiliary line ASL1 including the first bypass auxiliary line TASL1 may be disposed in the third gate conductive layer on the third gate insulating layer 125.

At least one shielding auxiliary electrode SHAE may be disposed in the first source-drain conductive layer on the second interlayer insulating layer 126 covering the third gate conductive layer.

At least one shielding auxiliary electrode SHAE may extend in parallel with the first bypass auxiliary line TASL1 and may overlap the intersection area between at least one second auxiliary line ASL2 (VASVL) paired with at least one data line DL1, DL2 and the first bypass auxiliary line TASL1.

Further, both ends of at least one shielding auxiliary electrode SHAE may overlap the first power line VDL.

As illustrated in FIG. 17, at least one shielding auxiliary electrode SHAE may be electrically connected to the first power line VDL through a shielding auxiliary connection hole SHACH.

In this way, since the potential of at least one shielding auxiliary electrode SHAE may be maintained at the constant voltage of the first power ELVDD, electrical shielding by at least one shielding auxiliary electrode SHAE may be made more robust.

Accordingly, although the data signal of at least one data line DL (DL1, DL2) intersecting the first bypass auxiliary line TASL1 may be supplied during the first period AT, due to at least one shielding auxiliary electrode SHAE, the data signal may be electrically separated from the first bypass auxiliary line TASL1, and thus may be readily maintained during the second period BT. Accordingly, distortion of the data signal of at least one data line DL (DL1, DL2) intersecting the first bypass auxiliary line TASL1 may be prevented, so that display quality may be improved.

Unlike the illustrations of FIGS. 16 and 17, at least one shielding auxiliary electrode SHAE may be electrically connected not to the first power line VDL but to another line that transmits a constant voltage. For example, at least one shielding auxiliary electrode SHAE may be electrically connected to, in addition to the first power line VDL, one of the gate initialization voltage line VGIL, the anode initialization voltage line VAIL, the bias voltage line VBL, and a wire (not illustrated) that transmits the second power ELVSS.

As illustrated in FIG. 16, the scan initialization line GIL may be adjacent to the first auxiliary line ASL1 (TASL1) and the gate initialization voltage line VGIL on a side (e.g., the lower side of FIG. 16) in the second direction DR2.

The scan write line GWL may be adjacent to the scan initialization line GIL on a side (e.g., the lower side of FIG. 16) in the second direction DR2.

The gate control line GCL may be adjacent to the scan write line GWL on a side (e.g., the lower side of FIG. 16) in the second direction DR2.

As an example, the scan write line GWL may be disposed in the first gate conductive layer on the first gate insulating layer 122.

According to an embodiment, the circuit layer 120 may further include a scan initialization auxiliary line GIAL overlapping the scan initialization line GIL, and a gate control auxiliary line GCAL overlapping the gate control line GCL.

Each of the scan initialization auxiliary line GIAL and the gate control auxiliary line GCAL may be disposed in the second gate conductive layer on the second gate insulating layer 123.

The second semiconductor layer may be disposed on the first interlayer insulating layer 124 covering the second gate conductive layer.

Each of the scan initialization line GIL and the gate control line GCL may be disposed in the third gate conductive layer on the third gate insulating layer 125 covering the second semiconductor layer.

The part of the gate control auxiliary line GCAL overlapping the second semiconductor layer may be the second light blocking layer of the third transistor T3, and the part of the gate control line GCL overlapping the second semiconductor layer may be the gate electrode of the third transistor T3.

Further, the part of the scan initialization auxiliary line GIAL overlapping the second semiconductor layer may be the second light blocking layer LB2 (see FIG. 6) of the fourth transistor T4, and the part of the scan initialization line GIL overlapping the second semiconductor layer may be the gate electrode G4 (see FIG. 6) of the fourth transistor T4.

However, the effects of the disclosure may not be restricted to the one set forth herein. The above and other effects of the disclosure will become more apparent to one of daily skill in the art to which the disclosure pertains by referencing the claims.

What is claimed is:

1. A display device comprising:
a substrate, a circuit layer disposed on the substrate, and an element layer disposed on the circuit layer, wherein
the substrate comprises a main region and a sub-region protruding from a side of the main region, the main region comprising a display area in which emission areas are arranged and a non-display area disposed around the display area,
the element layer comprises light emitting elements respectively disposed in the emission areas, and
the circuit layer comprises:
light emitting pixel drivers respectively electrically connected to the light emitting elements, the light emitting pixel drivers being arranged in a first direction and in a second direction;
data lines extending in the second direction and transmitting data signals to the light emitting pixel drivers;
first auxiliary lines extending in the first direction; and
second auxiliary lines extending in the second direction and respectively paired with the data lines, wherein
the first auxiliary lines comprise a first bypass auxiliary line electrically connected to a first data line disposed adjacent to an edge of the substrate in the first direction among the data lines,
the second auxiliary lines comprise a second bypass auxiliary line electrically connected to the first bypass auxiliary line, the second bypass auxiliary line being paired with a second data line which is spaced farther from the edge of the substrate than the first data line in the first direction among the data lines, and
the circuit layer further comprises at least one shielding auxiliary electrode which overlaps an intersection area between the first bypass auxiliary line and at least one data line disposed between the second bypass auxiliary line and the first data line in the first direction among the data lines.

2. The display device of claim 1, wherein
the at least one shielding auxiliary electrode is disposed on a first insulating layer covering the first auxiliary lines,
the data lines and the second auxiliary lines are disposed on a second insulating layer covering the shielding auxiliary electrode, and
in a third direction in which the first insulating layer and the second insulating layer are stacked on each other, the at least one shielding auxiliary electrode is disposed between the at least one data line and the first bypass auxiliary line.

3. The display device of claim 2, wherein the at least one shielding auxiliary electrode extends in parallel with the first bypass auxiliary line, and further overlaps an intersection area between the first bypass auxiliary line and at least one second auxiliary line respectively paired with the at least one data line among the second auxiliary lines.

4. The display device of claim 3, wherein each of the light emitting pixel drivers comprises:
a first transistor electrically connected between a first node and a second node;
a pixel capacitor electrically connected between a third node and a first power line transmitting a first power;
a second transistor electrically connected between the data line and the first node;
a third transistor electrically connected between the second node and the third node;
a fourth transistor electrically connected between a gate initialization voltage line and the third node;
a fifth transistor electrically connected between the first power line and the first node;
a sixth transistor electrically connected between the second node and the fourth node;
a seventh transistor electrically connected between a fourth node and an anode initialization voltage line transmitting an anode initialization voltage; and
an eighth transistor electrically connected between a bias voltage line and the first node, wherein
the first node is electrically connected to a first electrode of the first transistor,
the second node is electrically connected to a second electrode of the first transistor,
the third node is electrically connected to a gate electrode of the first transistor,
the fourth node is electrically connected to one of the light emitting elements,
the first power line extends in the second direction, is arranged between first auxiliary lines adjacent in the first direction, and is disposed on the second insulating layer, and
among the at least one shielding auxiliary electrode, two shielding auxiliary electrodes adjacent in the first direction are disposed adjacent to both sides of the first power line in the first direction.

5. The display device of claim 4, wherein the at least one shielding auxiliary electrode is electrically connected to the first power line.

6. The display device of claim 4, wherein the circuit layer further comprises:
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first interlayer insulating layer covering the second gate conductive layer;
a second semiconductor layer disposed on the first interlayer insulating layer;
a third gate insulating layer covering the second semiconductor layer;
a third gate conductive layer disposed on the third gate insulating layer;
a second interlayer insulating layer covering the third gate conductive layer;
a first source-drain conductive layer disposed on the second interlayer insulating layer;
a first planarization layer covering the first source-drain conductive layer;
a second source-drain conductive layer disposed on the first planarization layer; and
a second planarization layer covering the second source-drain conductive layer, and wherein
the first insulating layer comprises the second interlayer insulating layer, and
the second insulating layer comprises the first planarization layer.

7. The display device of claim 6, wherein
the third gate conductive layer comprises the first auxiliary lines,
the first source-drain conductive layer comprises the at least one shielding auxiliary electrode, and
the second source-drain conductive layer comprises the data lines, the second auxiliary lines, and the first power line.

8. The display device of claim 7, wherein
each of the third gate conductive layer, the first source-drain conductive layer, and the second source-drain conductive layer has a multilayer structure comprising a main layer and at least one sub-layer disposed on at least one of both sides of the main layer,
the main layer contains any one of molybdenum (Mo), aluminum (Al), chromium (Cr), gold (Au), nickel (Ni), neodymium (Nd), copper (Cu), and a combination thereof, and
the at least one sub-layer contains titanium (Ti).

9. The display device of claim 2, further comprising:
a display driving circuit disposed in the sub-region to supply the data signals to the data lines, wherein
the circuit layer further comprises data supply lines extending from the display driving circuit to the display area to transmit the data signals to the data lines,
among the data supply lines, a first data supply line which transmits a data signal of the first data line is electrically connected to the second bypass auxiliary line, and
among the data supply lines, a second data supply line which transmits a data signal of the second data line is directly electrically connected to the second data line.

10. The display device of claim 2, further comprising:
a display driving circuit disposed in the sub-region, wherein the circuit layer further comprises:
demux circuits disposed in the sub-region to output the data signals to the data lines based on a data mux signal supplied from the display driving circuit; and
data supply lines electrically connected between the demux circuits and the data lines to transmit the data signals to the data lines,
among the data supply lines, a first data supply line which transmits a data signal of the first data line is electrically connected to the first bypass auxiliary line, and
among the data supply lines, a second data supply line which transmits a data signal of the second data line is directly electrically connected to the second data line.

11. A display device comprising:
a substrate, a circuit layer disposed on the substrate, and an element layer disposed on the circuit layer, wherein
the substrate comprises a main region and a sub-region protruding from a side of the main region, the main region comprising a display area in which emission areas are arranged and a non-display area disposed around the display area,
the element layer comprises light emitting elements respectively disposed in the emission areas, and
the circuit layer comprises:
light emitting pixel drivers respectively electrically connected to the light emitting elements, the light emitting pixel drivers being arranged in a first direction and in a second direction;
data lines extending in the second direction to transmit data signals to the light emitting pixel drivers;
a first bypass auxiliary line extending in a first direction and electrically connected to a first data line disposed adjacent to an edge of the substrate in the first direction among the data lines;
a second bypass auxiliary line extending in the second direction and electrically connected to the first bypass auxiliary line, the second bypass auxiliary line being paired with a second data line which is spaced farther from the edge of the substrate than the first data line in the first direction among the data lines; and
at least one shielding auxiliary electrode overlapping at least one data line which intersects the first bypass auxiliary line among the data lines.

12. The display device of claim 11, wherein the circuit layer further comprises:
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first interlayer insulating layer covering the second gate conductive layer;
a second semiconductor layer disposed on the first interlayer insulating layer;
a third gate insulating layer covering the second semiconductor layer;
a third gate conductive layer disposed on the third gate insulating layer;
a second interlayer insulating layer covering the third gate conductive layer;
a first source-drain conductive layer disposed on the second interlayer insulating layer;
a first planarization layer covering the first source-drain conductive layer;
a second source-drain conductive layer disposed on the first planarization layer; and
a second planarization layer covering the second source-drain conductive layer, wherein
the third gate conductive layer comprises the first bypass auxiliary line,
the first source-drain conductive layer comprises the at least one shielding auxiliary electrode, and
the second source-drain conductive layer comprises the data lines and the second bypass auxiliary line.

13. The display device of claim 12, wherein
the at least one shielding auxiliary electrode extends in parallel with the first bypass auxiliary line, and
the at least one shielding auxiliary electrode is disposed between the at least one data line and the first bypass auxiliary line in a third direction in which the second interlayer insulating layer and the first planarization layer are stacked on each other.

14. The display device of claim 13, wherein
each of the third gate conductive layer, the first source-drain conductive layer, and the second source-drain conductive layer has a multilayer structure comprising a main layer and at least one sub-layer disposed on at least one of both sides of the main layer,
the main layer contains any one of molybdenum (Mo), aluminum (Al), chromium (Cr), gold (Au), nickel (Ni), neodymium (Nd), copper (Cu), and a combination thereof, and
the at least one sub-layer contains titanium (Ti).

15. The display device of claim 13, further comprising a display driving circuit disposed in the sub-region, wherein
the circuit layer further comprises:
demux circuits disposed in the sub-region to output the data signals to the data lines based on a data mux signal supplied from the display driving circuit; and
data supply lines electrically connected between the demux circuits and the data lines to transmit the data signals to the data lines,
among the data supply lines, a first data supply line which transmits the data signal of the first data line is electrically connected to the second bypass auxiliary line, and
among the data supply lines, a second data supply line which transmits the data signal of the second data line is directly electrically connected to the second data line.

16. The display device of claim 13, wherein each of the light emitting pixel drivers comprises:
a first transistor electrically connected between a first node and a second node;
a pixel capacitor electrically connected between a third node and a first power line transmitting a first power;
a second transistor electrically connected between the data line and the first node;
a third transistor electrically connected between the second node and the third node;
a fourth transistor electrically connected between a gate initialization voltage line and the third node;
a fifth transistor electrically connected between the first power line and the first node;
a sixth transistor electrically connected between the second node and the fourth node;
a seventh transistor electrically connected between a fourth node and an anode initialization voltage line transmitting an anode initialization voltage; and
an eighth transistor electrically connected between a bias voltage line and the first node, wherein
the first node is electrically connected to a first electrode of the first transistor,
the second node is electrically connected to a second electrode of the first transistor,
the third node is electrically connected to a gate electrode of the first transistor,
the fourth node is electrically connected to one of the light emitting elements, and
the at least one shielding auxiliary electrode is electrically connected to the first power line.
